(19) United States
(12) Patent Application Publication
(10) Pub. No.: US 2016/0065199 A1
(43) Pub. Date: Mar. 3, 2016

(54) AMPLITUDE DETECTOR

(71) Applicant: KABUSHIKI KAISHA TOSHIBA, Tokyo (JP)

(72) Inventor: Yousuke HAGIWARA, Kawasaki Kanagawa (JP)

(21) Appl. No.: 14/634,871

(22) Filed: Mar. 1, 2015

(30) Foreign Application Priority Data
Aug. 26, 2014 (JP) 2014-172056

(51) Int. Cl. H03K 5/24; H03G 3/30; H03K 5/02

(52) U.S. Cl. CPC H03K 5/2481; H03K 5/023; H03G 3/3042

(57) ABSTRACT

An amplitude detector includes a first amplitude detection transistor and an output terminal. The first amplitude detection transistor receives a first signal by a gate and a second signal that forms a differential pair with the first signal by a drain, and detects an amplitude of the differential pair. The output terminal outputs an amplitude signal in accordance with amplitude detected by the first amplitude detection transistor.

### CROSS-REFERENCE TO RELATED APPLICATION

This application is based upon and claims the benefit of priority from Japanese Patent Application No. 2014-172056, filed Aug. 26, 2014, the entire contents of which are incorporated herein by reference.

### FIELD

Embodiments described herein relate generally to an amplitude detector.

### BACKGROUND

In a communication instrument, in order to improve noise immunity of a signal, the signal is transmitted in the form of a differential signal in at least a part of a transmission path. When amplitude of the differential signal deviates from a range determined by a communication standard, a communication error may occur, and thus in the communication instrument, the amplitude of the differential signal is detected by an amplitude detector, and the detected amplitude is controlled such that the detected amplitude is a desired level. The amplitude detector is required to accurately detect the amplitude of the differential signal.

### DESCRIPTION OF THE DRAWINGS

FIG. 1 is a circuit diagram illustrating a configuration of an amplitude detector according to a first embodiment.

FIGS. 2A to 2C are waveform diagrams illustrating an operation of the amplitude detector according to the first embodiment.

FIG. 3 is a circuit diagram illustrating a configuration of an amplitude detector according to a modification example of the first embodiment.

FIG. 4 is a circuit diagram illustrating a configuration of an amplitude detector according to another modification example of the first embodiment.

FIG. 5 is a circuit diagram illustrating a configuration of an amplitude detector according to still another modification example of the first embodiment.

FIG. 6 is a circuit diagram illustrating a configuration of an amplitude detector of a second embodiment.

FIGS. 7A to 7C are waveform diagrams illustrating an operation of the amplitude detector according to the second embodiment.

FIG. 8 is a circuit diagram illustrating a configuration of an amplitude detector according to a modification example of the second embodiment.

FIG. 9 is a circuit diagram illustrating a configuration of an amplitude detector according to another modification example of the second embodiment.

FIG. 10 is a circuit diagram illustrating a configuration of an amplitude detector according to still another modification example of the second embodiment.

FIG. 11 is a circuit diagram illustrating a configuration of an amplitude detector according to a third embodiment.

FIG. 12 is a circuit diagram illustrating a configuration of an amplitude detector according to a fourth embodiment.

FIG. 13 is a circuit diagram illustrating a configuration of a communication instrument to which the amplitude detectors according to the first through fourth embodiments are applied.

FIG. 14 is a circuit diagram illustrating a configuration of a communication instrument to which an amplitude detector according to a basic configuration is applied.

FIG. 15 is a circuit diagram illustrating a configuration of the amplitude detector according to the basic configuration.

FIGS. 16A and 16B are complex plan views illustrating an operation of the amplitude detector according to the basic configuration.

### DETAILED DESCRIPTION

Embodiments provide an amplitude detector which is able to accurately detect amplitude of a differential signal.

In general, according to one embodiment, an amplitude detector includes a first amplitude detection transistor and an output terminal. The first amplitude detection transistor receives a first signal by a gate and a second signal that forms a differential pair with the first signal by a drain, and detects an amplitude of the differential pair. The output terminal outputs an amplitude signal in accordance with amplitude detected by the first amplitude detection transistor.

Hereinafter, amplitude detectors according to embodiments are described in detail with reference to the drawings. Furthermore, the present disclosure is not limited to the embodiments.

### First Embodiment

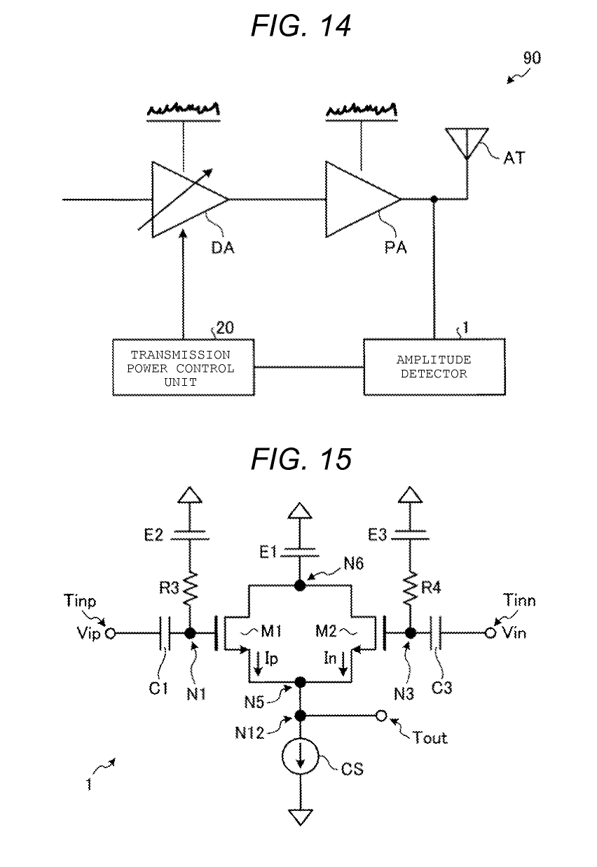

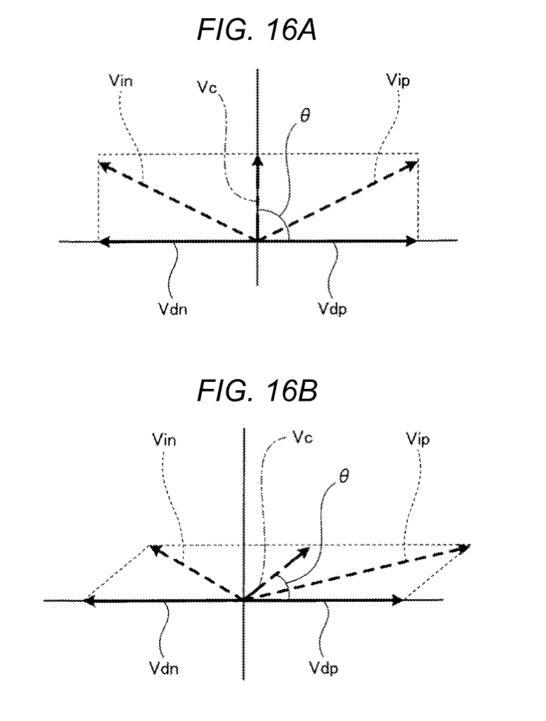

Before an amplitude detector 100 according to a first embodiment is described, an amplitude detector 1 according to a basic configuration is described with reference to FIGS. 14 through 16B. FIG. 14 is a diagram illustrating a configuration of a communication instrument 90 to which the amplitude detector 1 is applied. FIG. 15 is a diagram illustrating a configuration of the amplitude detector 1. FIGS. 16A and 16B are diagrams illustrating an operation of the amplitude detector 1.

In the communication instrument 90, in order to improve noise immunity of a signal, the signal is transmitted in the form of a differential signal in at least a part of a transmission path. When amplitude of the differential signal deviates from a range determined by a communication standard, a communication error may occur. In order to avoid occurrence of the communication error, as illustrated in FIG. 14, in the communication instrument 90, the amplitude of the differential signal is detected by the amplitude detector 1, and the detected amplitude is controlled such that the detected amplitude is in a target range. The target range is a range including a desired level.

Specifically, the communication instrument 90 includes the amplitude detector 1, a transmission power control unit 20, a driver amplifier DA, a power amplifier PA, and an antenna AT. The amplitude detector 1 detects the amplitude of the differential signal output from the power amplifier PA, and supplies an amplitude signal in accordance with the detected amplitude to the transmission power control unit 20. The transmission power control unit 20 controls the gain of the driver amplifier DA such that the received amplitude signal is in the target range. The target range is a range corresponding to a range determined by the communication standard with respect to the amplitude of the differential signal. The driver amplifier DA changes the gain according to control by the transmission power control unit 20, amplifies the differential signal by the changed gain, and supplies the differential signal to the power amplifier PA. The amplitude detector 1 is required to accurately detect the amplitude of the differential signal.

However, in the amplitude detector 1, when the differential signal is input, any in-phase component that is present can overlap with the differential signal. For example, when the driver amplifier DA includes a non-linear distortion which is present in a differential configuration, noise which is mixed into both an RF signal on a P side and an RF signal on an N side in the driver amplifier DA is likely to be the in-phase component. Similarly, when the power amplifier PA includes the non-linear distortion which is present in the differential configuration, noise which is mixed into both of an RF signal on a P side and an RF signal on an N side in the power amplifier PA is likely to be the in-phase component. In addition, the noise which is mixed into the RF signal on the P side and the RF signal on the N side from a power supply line is likely to be the in-phase component. In this case, in the amplitude detector 1, amplitude of a combined component of the differential signal and an in-phase signal is detected, and thus the amplitude of the differential signal is not accurately detected.

Specifically, as illustrated in FIG. 15, the amplitude detector 1 includes an input terminal (a first input or positive input terminal) Tinp, an input terminal (a second input or negative input terminal) Tinn, a capacitive element (a first capacitive element) C1, a capacitive element (a third capacitive element) C3, a resistive element R3, a resistive element R4, an amplitude detection transistor (a first amplitude detection transistor) M1, an amplitude detection transistor (a second amplitude detection transistor) M2, (M1 and M2 configured as a differential pair), a current source CS, and an output terminal Tout.

An RF signal (a first signal) Vip on a P side and a signal including a DC component among differential signals are input into the input terminal Tinp. An RF signal (a second signal) Vin on an N side and the signal including the DC component among the differential signals are input into the input terminal Tinn.

One end of the capacitive element C1 is electrically connected to the input terminal Tinp, and the other end thereof is connected to a gate of the amplitude detection transistor M1 through a node N1. Accordingly, the capacitive element C1 is able to block off the DC component of the signal which is input into the input terminal Tinp, and thus is able to transfer the RF signal Vip on the P side to the gate of the amplitude detection transistor M1.

One end of the capacitive element C3 is electrically connected to the input terminal Tinn, and the other end thereof is connected to a gate of the amplitude detection transistor M2 through a node N3. Accordingly, the capacitive element C3 is able to block the DC component of the signal which is input into the input terminal Tinn, and thus is able to transfer the RF signal Vin on the N side to the gate of the amplitude detection transistor M1.

The resistive element R3 adjusts a voltage value which is generated by a voltage source E2, and supplies an adjusted bias voltage Vb2 to the gate of the amplitude detection transistor M1 through the node N1. The bias voltage Vb2 is adjusted to be a level at which the amplitude detection transistor M1 is operated in the vicinity of a threshold value. The resistive element R4 adjusts a voltage value which is generated by a voltage source E3, and supplies the adjusted bias voltage Vb2 to the gate of the amplitude detection transistor M2 through the node N3. The bias voltage Vb2 is adjusted to be a level at which the amplitude detection transistor M2 is operated in the vicinity of the threshold value. A voltage source E1 generates a bias voltage Vb1, and supplies the bias voltage Vb1 to drains of the amplitude detection transistors M1 and M2 through a node N6.

The amplitude detection transistor M1 performs an ON and OFF operation according to the RF signal Vip on the P side while using the bias voltage Vb1 supplied to the drain in a state where the gate is biased by the bias voltage Vb2. For example, the amplitude detection transistor M1 is an NMOS transistor, and performs a source follower operation with the current source CS which is connected to a source side through nodes N5 and N12. Accordingly, the amplitude detection transistor M1 detects amplitude of the RF signal Vip on the P side, and supplies a signal (a drain current Ip) in accordance with a detection result to the node N5 side.

The amplitude detection transistor M2 performs an ON and OFF operation according to the RF signal Vin on the N side while using the bias voltage Vb1 supplied to the drain in a state where the gate is biased by the bias voltage Vb2. For example, the amplitude detection transistor M2 is an NMOS transistor, and performs a source follower operation with the current source CS which is connected to a source side through the nodes N5 and N12. Accordingly, the amplitude detection transistor M2 detects amplitude of the RF signal Vin on the N side, and supplies a signal (a drain current In) in accordance with a detection result to the node N5 side.

The output terminal Tout receives the signal in accordance with the detection result of the amplitude detection transistor M1 and the signal in accordance with the detection result of the amplitude detection transistor M2 through the nodes N5 and N12, and outputs an amplitude signal Vo in accordance with the received signal. That is, the output terminal Tout outputs the amplitude signal Vo in accordance with the amplitude detected by the amplitude detection transistor M1 and the amplitude detected by the amplitude detection transistor M2.

For example, when the in-phase component is not mixed into the RF signal Vip on the P side and the RF signal Vin on the N side, each RF signal is expressed by the following Expression 1 and Expression 2.

Vip=α sin ωct Expression 1

Vin=−α sin ωct Expression 2

In each of Expression 1 and Expression 2, a right side indicates a differential component. The amplitude detection transistors M1 and M2 have a squared non-linear property with respect to a voltage Vgs between a gate and a source and a voltage Vds between a source and a drain, and thus when a squared non-linear coefficient is set to k, the amplitude signal Vo output from the output terminal Tout is shown by the following Expression 3.

$$\begin{matrix}Vo = {k ( Vip )}^{2} + {k ( Vin )}^{2} \\ = k ( {α}^{2} - {α}^{2} cos 2 ω ct )\end{matrix} \qquad Expression 3$$

In Expression 3, k(Vip)² indicates a component in accordance with the detection result (the drain current Ip) of the amplitude detection transistor M1, and k(Vin)² indicates a component in accordance with the detection result (the drain current In) of the amplitude detection transistor M2. In addition, a term of “α²” indicates the DC component, and a term of “α² cos 2 ω ct” indicates a secondary component (a component including a frequency which is twice a fundamental frequency ωc). A primary component (a fundamental wave component including the fundamental frequency ωc) is cancelled since the amplitude detector 1 has a differential configuration.

On the other hand, if the in-phase component is mixed into the RF signal Vip on the P side and the RF signal Vin on the N side, when a phase difference between the in-phase component and the differential component on the P side is set to θ (refer to FIGS. 16A and 16B), each RF signal is expressed by the following Expression 4 and Expression 5.

Vip=α sin ωct+β sin(ω ct+θ) Expression 4

Vin=−α sin ωct+β sin(ω ct+θ) Expression 5

In each of Expression 4 and Expression 5, a first term on a right side indicates the differential component, and a second term on the right side indicates the in-phase component. The amplitude detection transistors M1 and M2 have a squared non-linear property with respect to the voltage Vgs between the gate and the source and the voltage Vds between the source and the drain, and thus when the squared non-linear coefficient is set to k, the amplitude signal Vo output from the output terminal Tout is shown by the following Expression 6.

$$\begin{matrix}Vo = {k ( Vip )}^{2} + {k ( Vin )}^{2} \\ = k \{ \begin{matrix}{α}^{2} + {β}^{2} + 2 α β cos θ - {α}^{2} cos 2 ω ct - \\ {β}^{2} {cos}^{2} ( ω ct + θ ) - 2 α β cos ( 2 ω ct + θ )\end{matrix} \}\end{matrix} \qquad Expression 6$$

In Expression 3, the term “α²+β²+2αβ cos θ” indicates the DC component, and the term “α² cos 2ω ct−β² cos 2 (ω ct+θ)−2αβ cos(2ω ct+θ)” indicates the secondary component (the component including the frequency twice the fundamental frequency ωc). The primary component (the fundamental wave component including the fundamental frequency ωc) is cancelled since the amplitude detector 1 is configured with the differential configuration.

It is known that the DC component “k(α²+β²+2αβ cos θ)” shown by the Expression 3 is a component corresponding to the detected amplitude, and is a component which is changed according to magnitude β of the in-phase component and the phase difference θ between the in-phase component and the differential component. That is, the amplitude detection transistors M1 and M2 detect the amplitude of the combined component of the differential signal and the in-phase signal. In this case, as illustrated in FIGS. 16A and 16B, the amplitude of the differential signal is not accurately detected. Each of FIGS. 16A and 16B is a view in the complex plane illustrating an operation of the amplitude detector 1, in which the horizontal axis indicates the real component of a signal, and the vertical axis indicates the imaginary component of the signal.

For example, when a case of FIG. 16A and a case of FIG. 16B are compared to each other, differential components Vdp and Vdn shown by a vector in a solid line are identical to each other, but the phase differences θ between the differential components Vdp on the P side and the in-phase components Vc shown by a vector in a dashed-dotted line are different from each other. Accordingly, the amplitude of the RF signals Vip and Vin shown by a vector in a broken line as a combined signal in FIG. 16A and the amplitude of the RF signals Vip and Vin shown by a vector in a broken line as a combined signal in FIG. 16B tend to be different from each other. That is, a detection value of the amplitude of the differential signal varies due to an influence of the in-phase component, and thus the differential component (a desired signal) is not accurately detected.

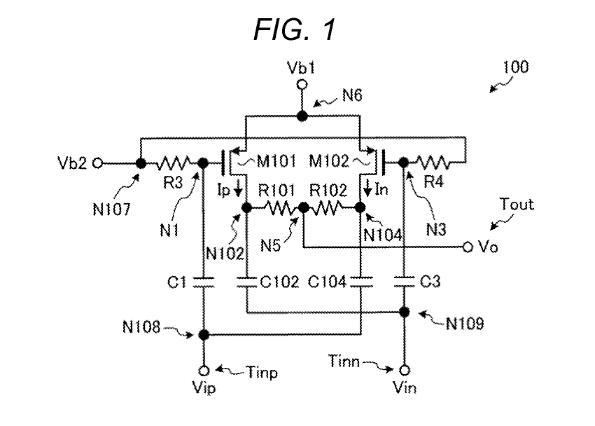

Therefore, in the first embodiment, as illustrated in FIG. 1, a different configuration of an amplitude detector 100 is devised, and thus the influence of the in-phase component is reduced. Hereinafter, portions which are different from the basic configuration are mainly described.

Specifically, the amplitude detector 100 includes an amplitude detection transistor (a first amplitude detection transistor) M101 and an amplitude detection transistor (a second amplitude detection transistor) M102 instead of the amplitude detection transistor M1 and the amplitude detection transistor M2 (refer to FIG. 15) (M101 and M102 configured as a differential pair), and further includes a capacitive element (a second capacitive element, a load capacitance) C102, a capacitive element (a fourth capacitive element, a load capacitance) C104, a resistive element (a first resistive element or first load resistor) R101, and a resistive element (a second resistive element or second load resistor) R102. The amplitude detector 100 does not include the current source CS (refer to FIG. 15).

One end of the capacitive element C102 is connected to the input terminal Tinn, and the other end thereof is connected to a drain of the amplitude detection transistor M101 through a node N102. Accordingly, the capacitive element C102 is able to block a DC component among signals which are input into the input terminal Tinn, and thus is able to transfer an RF signal Vin on an N side to the drain of the amplitude detection transistor M101.

One end of the capacitive element C104 is connected to the input terminal Tinp, and the other end thereof is connected to a drain of the amplitude detection transistor M102 through a node N104. Accordingly, the capacitive element C104 is able to block a DC component among signals which are input into the input terminal Tinp, and thus is able to transfer an RF signal Vip on a P side to the drain of the amplitude detection transistor M102. A capacitance value of the capacitive element C1 (an input capacitance), a capacitance value of the capacitive element C102, a capacitance value of the capacitive element C3 (an input capacitance, and a capacitance value of the capacitive element C104 may be equal to each other.

One end of the resistive element R101 is connected to the node N102, and the other end thereof is connected to a node N5. Accordingly, the resistive element R101 converts a current which is supplied according to a drain current Ip of the amplitude detection transistor M101 into a voltage, and adjusts a voltage value thereof.

One end of the resistive element R102 is connected to the node N104, and the other end thereof is connected to the node N5. Accordingly, the resistive element R102 converts a current which is supplied according to a drain current In of the amplitude detection transistor M102 into a voltage, and adjusts a voltage value thereof.

Furthermore, a resistance value of the resistive element R101 and a resistance value of the resistive element R102 may be adjusted such that an absolute value of amplitude of a primary component supplied from the amplitude detection transistor M101 and an absolute value of amplitude of a primary component supplied from the amplitude detection transistor M102 are equal to each other. For example, when a dimension of the amplitude detection transistor M101 and a dimension of the amplitude detection transistor M102 are equal to each other, the resistance value of the resistive element R102 and the resistance value of the resistive element R101 may be equal to each other. When the dimension of the amplitude detection transistor M101 and the dimension of the amplitude detection transistor M102 are different from each other, the resistance value of the resistive element R102 and the resistance value of the resistive element R101 may be determined to offset an influence due to a difference in the dimensions.

The amplitude detection transistor M101, for example, is a PMOS transistor. A gate of the amplitude detection transistor M101 is connected to the other end of the capacitive element C1 through a node N1, and a drain thereof is connected to the other end of the capacitive element C102 through the node N102. Accordingly, the amplitude detection transistor M101 receives the RF signal (a first signal) Vip on the P side by the gate, and receives the RF signal (a second signal) Vin on the N side by the drain.

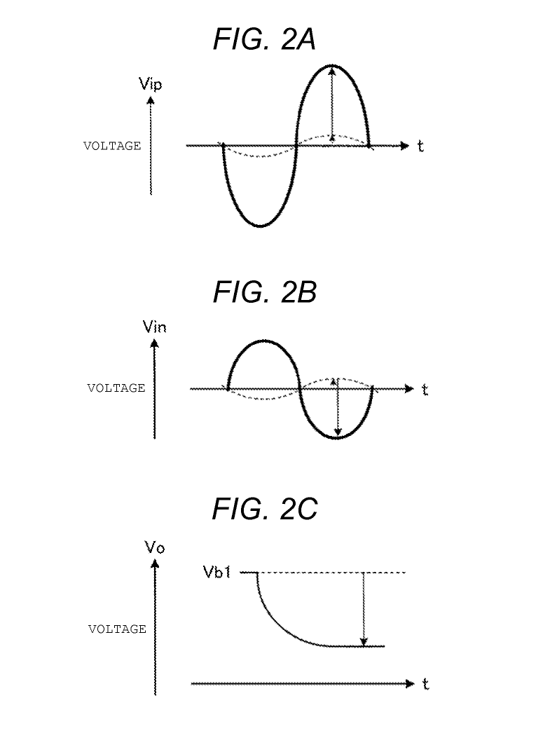

At this time, as illustrated by a broken line in FIGS. 2A and 2B, an in-phase component included in the RF signal Vip on the P side and an in-phase component included in the RF signal Vin on the N side vary substantially equally in time, and thus it is possible to offset an influence of the in-phase component with respect to an operation of the amplitude detection transistor M101. FIGS. 2A and 2B are waveform diagrams illustrating the operation of the amplitude detector 100, and each of the RF signal Vip on the P side and the RF signal Vin on the N side is illustrated by a solid line. That is, the amplitude detection transistor M101 is able to detect amplitude (a magnitude of an arrow in a solid line illustrated in FIG. 2A) of the RF signal Vip on the P side while eliminating the influence of the in-phase component, and is able to supply a detection result in which the influence of the in-phase component is eliminated to an output terminal Tout.

The amplitude detection transistor M102, for example, is a PMOS transistor. A gate of the amplitude detection transistor M102 is connected to the other end of the capacitive element C3 through a node N3, and a drain thereof is connected to the other end of the capacitive element C104 through the node N104. Accordingly, the amplitude detection transistor M102 receives the RF signal (a second signal) Vin on the N side by the gate, and receives the RF signal (a first signal) Vip on the P side by the drain.

At this time, as illustrated by a broken line in FIGS. 2A and 2B, the in-phase component included in the RF signal on the P side and the in-phase component included in the RF signal on the N side vary substantially equally in time, and thus it is possible to offset the influence of the in-phase component with respect to an operation of the amplitude detection transistor M102. That is, the amplitude detection transistor M102 is able to detect amplitude (a magnitude of an arrow in a solid line illustrated in FIG. 2B) of the RF signal on the N side while eliminating the influence of the in-phase component, and is able to supply a detection result in which the influence of the in-phase component is eliminated to the output terminal Tout.

A bias voltage Vb2 is supplied to the gate of the amplitude detection transistor M101 through a node N107 and the resistive element R3, and is supplied to the gate of the amplitude detection transistor M102 through the node N107 and the resistive element R4.

The output terminal Tout receives the detection result of the amplitude detection transistor M101 through the node N102, the resistive element R101, and the node N5, and receives the detection result of the amplitude detection transistor M102 through the node N104, the resistive element R102, and the node N5. The detection result of the amplitude detection transistor M101 and the detection result of the amplitude detection transistor M102 which are received by the output terminal Tout are substantially equal to each other, and have a voltage of which a level decreases according to an amplitude value detected based on a bias voltage Vb1. Accordingly, the output terminal Tout is able to output the amplitude signal Vo as illustrated by a solid line in FIG. 2C. That is, when the in-phase component is mixed into the RF signal Vip on the P side and the RF signal Vin on the N side, the amplitude signal Vo is able to indicate a value (for example, a value expressed by Expression 3) in accordance with amplitude of a differential signal at a decrease level width from the bias voltage Vb1.

In the amplitude detector 100, it is possible to easily make a load seen from the input terminal Tinp and a load seen from the input terminal Tinn equal to each other. For example, each of the capacitive element C1 and the capacitive element C104 is connected to the input terminal Tinp through a node N108. From the input terminal Tinp, the capacitive element C1, a gate capacitance of the amplitude detection transistor M101, the capacitive element C104, and a parasitic capacitance on the drain side of the amplitude detection transistor M102 are considered as the load. Each of the capacitance C102 and the capacitance C3 is connected to the input terminal Tinn through a node N109. From the input terminal Tinn, the capacitive element C3, a gate capacitance of the amplitude detection transistor M102, the capacitive element C102, and a parasitic capacitance on the drain side of the amplitude detection transistor M101 are considered as the load. When the capacitance value of the capacitive element C1, the capacitance value of the capacitive element C102, the capacitance value of the capacitive element C3, and the capacitance value of the capacitive element C104 are equal to each other, and the dimension of the amplitude detection transistor M101 and the dimension of the amplitude detection transistor M102 are equal to each other, the load seen from the input terminal Tinp and the load seen from the input terminal Tinn are substantially equal to each other.

In addition, in the amplitude detector 100, the primary component of the RF signal on the P side which is transferred from the amplitude detection transistor M101 to the node N5 and the primary component of the RF signal on the N side which is transferred from the amplitude detection transistor M102 to the node N5 are in a differential relationship with each other. Accordingly, the primary component of the RF signal on the P side and the primary component of the RF signal on the N side are able to be cancelled in the node N5, and thus the DC component and a secondary component of the RF signal are transferred from the amplitude detection transistors M101 and M102 to the output terminal Tout. Furthermore, in order to simplify the drawings, the secondary component of the RF signal is omitted in FIG. 2C.

As described above, in the amplitude detector 100 according to the first embodiment, the amplitude detection transistors M101 and M102 receive the RF signal on the P side by the gate, and receive the RF signal on the N side by the drain. When the in-phase component overlaps with the differential signal, in the amplitude detection transistors M101 and M102, the in-phase component in each of the gate and the drain varies substantially equally in time, and thus it is possible to offset the influence of the in-phase component. That is, the amplitude detection transistors M101 and M102 are able to detect the amplitude of the RF signals Vip and Vin while eliminating the influence of the in-phase component, and thus are able to supply the detection result in which the influence of the in-phase component is eliminated to the output terminal Tout. Accordingly, the output terminal Tout is able to output the amplitude signal Vo in which the influence of the in-phase component is eliminated, in accordance with the amplitude detected by the amplitude detection transistors M101 and M102. That is, in the amplitude detector 100, it is possible to suppress the influence of the in-phase component, and it is possible to accurately detect the amplitude of the differential signal.

In addition, in the amplitude detector 100 of the first embodiment, one end of the capacitive element C1 is connected to the input terminal Tinp, and the other end of the capacitive element C1 is connected to the gate of the amplitude detection transistor M101 through the node N1. One end of the capacitive element C102 is connected to the input terminal Tinn, and the other end of the capacitive element C102 is connected to the drain of the amplitude detection transistor M101 through the node N102. Accordingly, it is possible to block the DC component among the signals which are input into the input terminal Tinp and to supply the signal to the gate of the amplitude detection transistor M101, and it is possible to block the DC component among the signals which are input into the input terminal Tinn and to supply the signal to the drain of the amplitude detection transistor M101.

Similarly, in the amplitude detector 100, one end of the capacitive element C3 is connected to the input terminal Tinn, and the other end of the capacitive element C3 is connected to the gate of the amplitude detection transistor M102 through the node N3. One end of the capacitive element C104 is connected to the input terminal Tinp, and the other end of the capacitive element C104 is connected to the drain of the amplitude detection transistor M102 through the node N104. Accordingly, it is possible to block the DC component among the signals which are input into the input terminal Tinn and to supply the signal to the gate of the amplitude detection transistor M102, and it is possible to block the DC component among the signals which are input into the input terminal Tinp and to supply the signal to the drain of the amplitude detection transistor M102.

In addition, in the amplitude detector 100 according to the first embodiment, the output terminal Tout outputs the amplitude signal Vo in accordance with the amplitude detected by the amplitude detection transistor M101 and the amplitude detected by the amplitude detection transistor M102. That is, since the amplitude detector 100 has a differential configuration, the primary component of the RF signal on the P side and the primary component of the RF signal on the N side can be cancelled in the node N5, and thus the amplitude of the differential signal is easily and accurately detected.

In addition, in the amplitude detector 100 according to the first embodiment, resistive element R101 is connected between the amplitude detection transistor M101 and the output terminal Tout, and the resistive element R102 is connected between the amplitude detection transistor M102 and the output terminal Tout. Accordingly, the resistance value of the resistive element R101 and the resistance value of the resistive element R102 are able to be adjusted such that the absolute value of the amplitude of the primary component supplied from the amplitude detection transistor M101 and the absolute value of the amplitude of the primary component supplied from the amplitude detection transistor M102 are equal to each other. As a result, the primary component of the RF signal on the P side and the primary component of the RF signal on the N side are easily cancelled in the node N5.

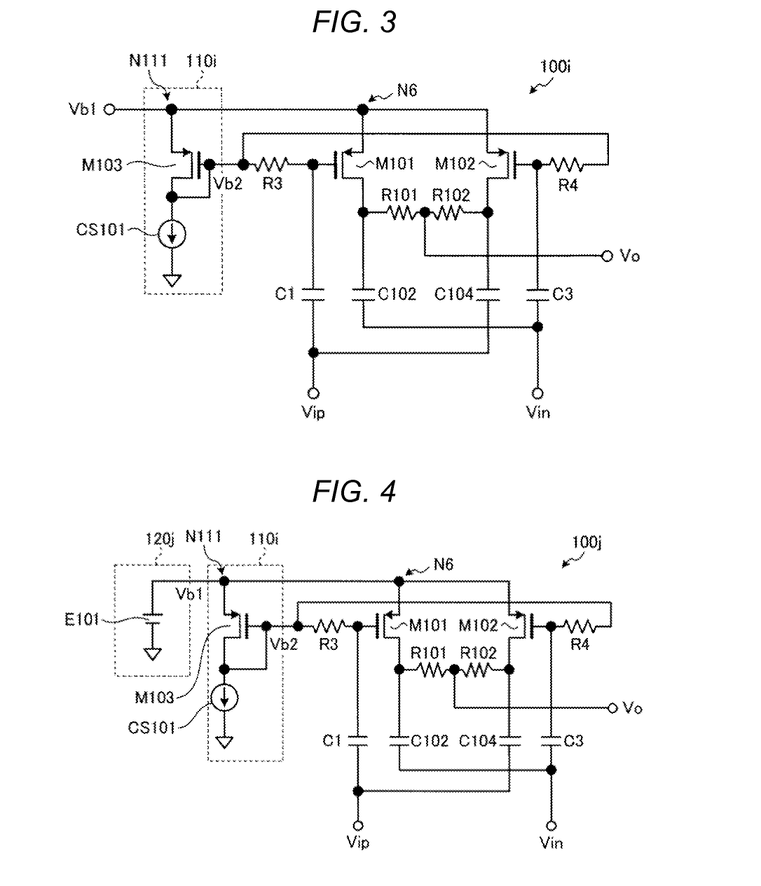

Furthermore, an amplitude detector 100i may include a bias generation circuit 110i as illustrated in FIG. 3. FIG. 3 is a diagram illustrating a configuration of the amplitude detector 100i. The bias generation circuit 110i generates the bias voltage Vb2 (second bias voltage) by using the bias voltage Vb1 (first bias voltage), and supplies the bias voltage Vb2 to the gate of the current detection transistors M101 and M102. The bias generation circuit 110i includes a bias transistor M103 and a current source CS101. The bias transistor M103, for example, is a PMOS transistor. A source of the bias transistor M103 is connected to the bias voltage Vb1 through a node N111, and a drain thereof is connected to the current source CS101 and a gate thereof (in a diode-configuration). One end of the current source CS101 is connected to a ground potential, and the other end thereof is connected to the bias transistor M103. The gate of the bias transistor M103 is connected to the gate of the current detection transistors M101 and M102 through the resistive elements R3 and R4. Accordingly, the bias transistor M103 generates the bias voltage Vb2 in accordance with a current generated by the current source CS101, and supplies the bias voltage Vb2 to the gate of the current detection transistors M101 and M102.

In addition, an amplitude detector 100j may include a bias generation circuit 120j as illustrated in FIG. 4. FIG. 4 is a diagram illustrating a configuration of the amplitude detector 100j. At this time, the amplitude detector 100j may include the bias generation circuit 110i. The bias generation circuit 120j generates the bias voltage Vb1, and supplies the bias voltage Vb1 to the current detection transistors M101 and M102 and the bias generation circuit 110i. The bias generation circuit 120j includes a voltage source E101 (first bias voltage source). One end (−side) of the voltage source E101 is connected to the ground potential, and the other end (+side) thereof is connected to the node N111. The voltage source E101 generates the bias voltage Vb1 based on the ground potential, supplies the bias voltage Vb1 to the source of the current detection transistors M101 and M102 through the nodes N111 and N6, and supplies the bias voltage Vb1 to the source of the bias transistor M103 through the node N111.

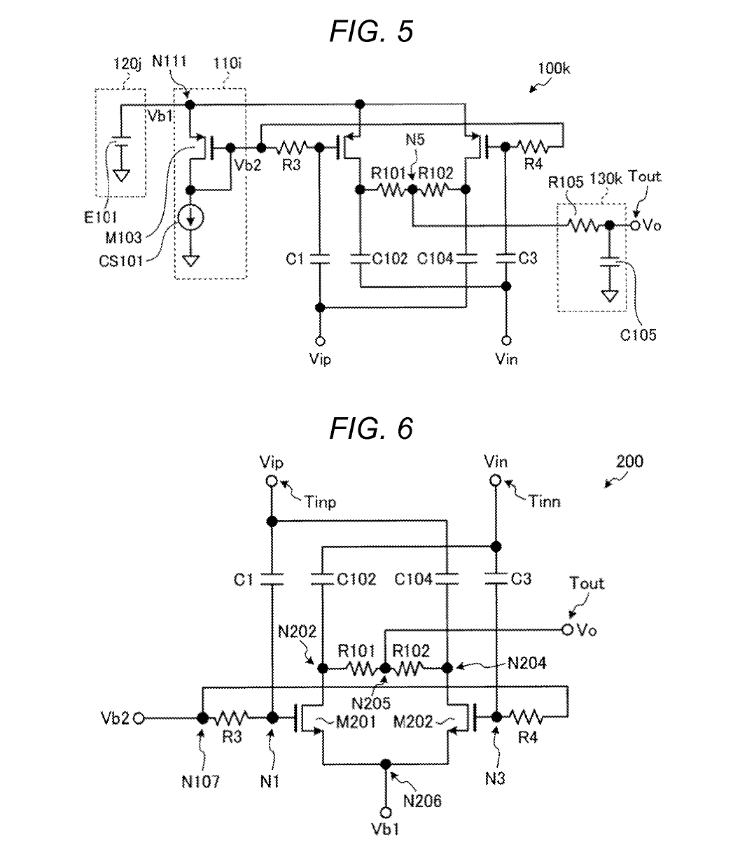

In addition, an amplitude detector 100k may include a low-pass filter 130k as illustrated in FIG. 5. FIG. 5 is a diagram illustrating a configuration of the amplitude detector 100k. The low-pass filter 130k is electrically connected between the node N5 and the output terminal Tout. The low-pass filter 130k includes a resistive element R105 and a capacitive element C105. The resistive element R105 is inserted into a line connecting the node N5 and the output terminal Tout. One end of the capacitive element C105 is connected to the ground potential, and the other end thereof is connected to the line connecting the node N5 and the output terminal Tout. Accordingly, the low-pass filter 130k is able to dampen a component having a frequency greater than or equal to a cutoff frequency among signals supplied from the node N5, and is able to transfer the signal to the output terminal Tout. When the cutoff frequency is set to be less than a frequency twice a fundamental frequency ωc, the low-pass filter 130k is able to eliminate the secondary component among the signals supplied from the node N5, and is able to transfer the DC component to the output terminal Tout. Accordingly, it is possible to more accurately detect the amplitude of the differential signal.

### Second Embodiment

Next, an amplitude detector 200 according to a second embodiment will be described. Hereinafter, portions which are different from the first embodiment are mainly described.

In the first embodiment, the case where the PMOS transistor is used as the current detection transistors M101 and M102 is depicted, and in the second embodiment, the case where an NMOS transistor is used as current detection transistors M201 and M202 is depicted.

Specifically, as illustrated in FIG. 6, the amplitude detector 200 includes an amplitude detection transistor (a first amplitude detection transistor) M201 and an amplitude detection transistor (a second amplitude detection transistor) M202 instead of the amplitude detection transistor M101 and the amplitude detection transistor M102 (refer to FIG. 1). FIG. 6 is a diagram illustrating a configuration of the amplitude detector 200.

The amplitude detection transistor M201, for example, is an NMOS transistor. A source of the amplitude detection transistor M201 is connected to the bias voltage Vb1 through a node N206, and a drain thereof is connected to an output terminal Tout through a node N202, the resistive element R101, and a node N205. In addition, a gate of the amplitude detection transistor M201 is connected to the other end of the capacitive element C1 through the node N1, and the drain thereof is connected to the other end of the capacitive element C102 through the node N202. Accordingly, the amplitude detection transistor M201 receives the RF signal (the first signal) Vip on the P side by the gate, and receives the RF signal (the second signal) Vin on the N side by the drain.

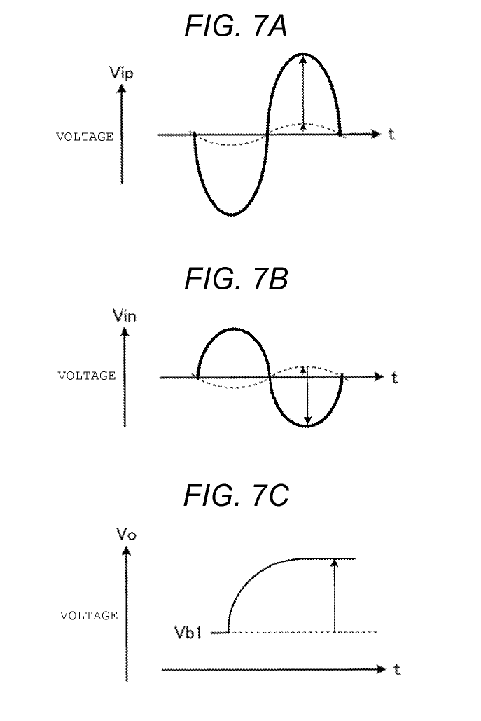

As illustrated by a broken line in FIGS. 7A and 7B, the in-phase component included in the RF signal Vip on the P side and the in-phase component included in the RF signal Vin on the N side vary substantially equally in time, and thus it is possible to offset the influence of the in-phase component with respect to an operation of the amplitude detection transistor M201. FIGS. 7A and 7B are waveform diagrams illustrating an operation of the amplitude detector 200, and each of the RF signal Vip on the P side and the RF signal Vin on the N side is illustrated by a solid line. That is, the amplitude detection transistor M201 is able to detect amplitude (a magnitude of an arrow in a solid line illustrated in FIG. 7A) of the RF signal Vip on the P side while eliminating the influence of the in-phase component, and is able to supply a detection result in which the influence of the in-phase component is eliminated to an output terminal Tout.

The amplitude detection transistor M202, for example, is an NMOS transistor. A source of the amplitude detection transistor M202 is connected to the bias voltage Vb1 through the node N206, and a drain thereof is connected to the output terminal Tout through a node N204, the resistive element R102, and the node N205. In addition, a gate of the amplitude detection transistor M202 is connected to the other end of the capacitive element C3 through the node N3, and the drain thereof is connected to the other end of the capacitive element C104 through the node N204. Accordingly, the amplitude detection transistor M202 receives the RF signal (the second signal) Vin on the N side by the gate, and receives the RF signal (the first signal) Vip on the P side by the drain.

As illustrated by a broken line in FIGS. 7A and 7B, the in-phase component included in the RF signal on the P side and the in-phase component included in the RF signal on the N side vary substantially equally in time, and thus it is possible to offset the influence of the in-phase component with respect to an operation of the amplitude detection transistor M202. That is, the amplitude detection transistor M202 is able to detect amplitude (a magnitude of an arrow in a solid line illustrated in FIG. 7B) of the RF signal on the N side while eliminating the influence of the in-phase component, and is able to supply a detection result in which the influence of the in-phase component is eliminated to the output terminal Tout.

The output terminal Tout receives the detection result of the amplitude detection transistor M201 through the node N202, the resistive element R101, and the node N205, and receives the detection result of the amplitude detection transistor M202 through the node N204, the resistive element R102, and the node N205. The detection result of the amplitude detection transistor M201 and the detection result of the amplitude detection transistor M202 which are received by the output terminal Tout are substantially equal to each other, and have a voltage of which a level increases according to an amplitude value detected based on the bias voltage Vb1. Accordingly, the output terminal Tout is able to output the amplitude signal Vo as illustrated by a solid line in FIG. 7C. That is, when the in-phase component is mixed into the RF signal Vip on the P side and the RF signal Vin on the N side, the amplitude signal Vo is able to indicate a value (for example, a value shown by Expression 3) in accordance with amplitude of a differential signal at an increase level width from the bias voltage Vb1.

As described above, in the amplitude detector 200 according to the second embodiment, the amplitude detection transistors M201 and M202 are able to detect the amplitude of the RF signals Vip and Vin while eliminating the influence of the in-phase component, and are able to supply the detection result in which the influence of the in-phase component is eliminated to the output terminal Tout. Accordingly, the output terminal Tout is able to output the amplitude signal Vo in which the influence of the in-phase component is eliminated, in accordance with the amplitude detected by the amplitude detection transistors M201 and M202. That is, according to the second embodiment, it is possible to suppress the influence of the in-phase component, and it is possible to accurately detect the amplitude of the differential signal.

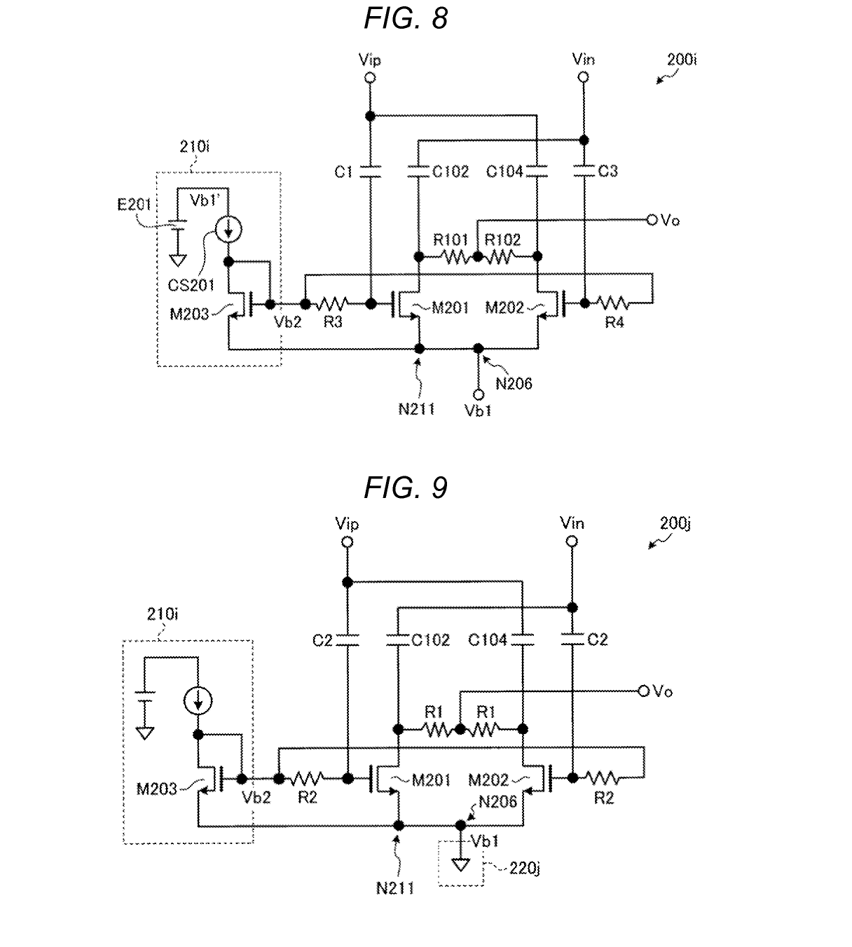

Furthermore, an amplitude detector 200i may include a bias generation circuit 210i as illustrated in FIG. 8. FIG. 8 is a diagram illustrating a configuration of the amplitude detector 200i. The bias generation circuit 210i generates the bias voltage Vb2 by using the bias voltage Vb1, and supplies the bias voltage Vb2 to the gate of the current detection transistors M201 and M202. The bias generation circuit 210i includes a voltage source E201, a bias transistor M203, and a current source CS201. One end (−side) of the voltage source E201 is connected to the ground potential, and the other end (+side) thereof is connected to the current source CS201. The voltage source E201 generates a predetermined voltage Vb1′ based on the ground potential, and supplies the voltage Vb1′ to the current source CS201. The bias transistor M203, for example, is an NMOS transistor. A source of the bias transistor M203 is connected to the bias voltage Vb1 through the nodes N211 and N206, and a drain thereof is connected to the current source CS201 and a gate thereof (in a diode-configuration). The gate of the bias transistor M203 is connected to the gate of the current detection transistors M201 and M202 through the resistive elements R3 and R4. Accordingly, the bias transistor M203 generates the bias voltage Vb2 in accordance with a current generated by the current source CS201, and supplies the bias voltage Vb2 to the gate of the current detection transistors M201 and M202.

In addition, an amplitude detector 200j may include a bias generation circuit 220j as illustrated in FIG. 9. FIG. 9 is a diagram illustrating a configuration of the amplitude detector 200j. At this time, the amplitude detector 200j may include the bias generation circuit 210i. The bias generation circuit 220j generates the bias voltage Vb1, and supplies the bias voltage Vb1 to the current detection transistors M201 and M202 and the bias generation circuit 210i. The bias generation circuit 220j includes the ground potential. The bias generation circuit 220j generates the ground potential as the bias voltage Vb1, supplies the ground potential to the source of the current detection transistors M201 and M202 through the nodes N211 and N206, and supplies the ground potential to the source of the bias transistor M203 through the node N206.

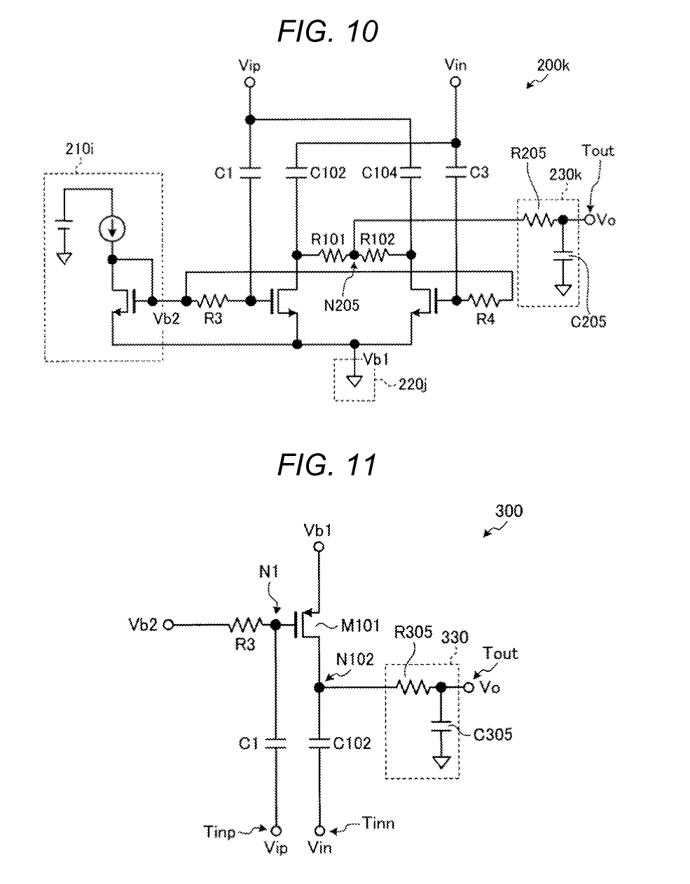

In addition, an amplitude detector 200k may include a low-pass filter 230k as illustrated in FIG. 10. FIG. 10 is a diagram illustrating a configuration of the amplitude detector 200k. The low-pass filter 230k is electrically connected between the node N205 and the output terminal Tout. The low-pass filter 230k includes a resistive element R205 and a capacitive element C205. The resistive element R205 is inserted into a line connecting the node N205 and the output terminal Tout. One end of the capacitive element C205 is connected to the ground potential, the other end thereof is connected to the line connecting the node N205 and the output terminal Tout. Accordingly, the low-pass filter 230k is able to dampen a component having a frequency greater than or equal to a cutoff frequency among signals supplied from the node N205, and is able to transfer the signal to the output terminal Tout. When the cutoff frequency is set to be less than a frequency twice a fundamental frequency ωc, the low-pass filter 230k is able to eliminate the secondary component among the signals supplied from the node N205, and is able to transfer the DC component to the output terminal Tout. Accordingly, it is possible to more accurately detect the amplitude of the differential signal.

### Third Embodiment

Next, an amplitude detector 300 according to a third embodiment is described. Hereinafter, portions which are different from the first embodiment are mainly described.

In the first embodiment, the amplitude detector 100 has a differential configuration, and in the third embodiment, the amplitude detector 300 has a non-differential configuration.

Specifically, as illustrated in FIG. 11, in the amplitude detector 300, one-sided configuration of the differential configuration illustrated in FIG. 1 is omitted, and the capacitive element (the third capacitive element) C3, the resistive element R101, the resistive element R102, the resistive element R4, and the amplitude detection transistor (the second amplitude detection transistor) M102 are not included. The amplitude detector 300 further includes a low-pass filter 330. FIG. 11 is a diagram illustrating a configuration of the amplitude detector 300.

The low-pass filter 330 is electrically connected between the node N102 and the output terminal Tout. The low-pass filter 330 includes a resistive element R305 and a capacitive element C305. The resistive element R305 is inserted into a line connecting the node N102 and the output terminal Tout. One end of the capacitive element C305 is connected to the ground potential, and the other end thereof is connected to the line connecting the node N102 and the output terminal Tout. Accordingly, the low-pass filter 330 is able to dampen a component having a frequency greater than or equal to a cutoff frequency among signals supplied from the node N102, and is able to transfer the signal to the output terminal Tout. When a resistance value of the resistive element R305 and a capacitance value of the capacitive element C305 are set such that the cutoff frequency is less than the fundamental frequency ωc, the low-pass filter 330 is able to eliminate the primary component and the secondary component among the signals supplied from the node N102, and is able to transfer the DC component to the output terminal Tout.

Furthermore, the third embodiment is identical to the first embodiment in that the amplitude detection transistor M101 receives the RF signal (the first signal) Vip on the P side by the gate, and receives the RF signal (the second signal) Vin on the N side by the drain.

Thus, in the amplitude detector 300 according to the third embodiment, the amplitude detection transistor M101 is able to detect the amplitude of the RF signals Vip and Vin while eliminating the influence of the in-phase component, and is able to supply the detection result in which the influence of the in-phase component is eliminated to the output terminal Tout. Accordingly, the output terminal Tout is able to output the amplitude signal Vo in which the influence of the in-phase component is eliminated in accordance with the amplitude detected by the amplitude detection transistor M101. That is, according to the third embodiment, it is possible to suppress the influence of the in-phase component, and it is possible to accurately detect the amplitude of the differential signal.

In addition, in the amplitude detector 300 of the third embodiment, the low-pass filter 330 is able to eliminate the primary component and the secondary component among the signals supplied from the node N102, and is able to transfer the DC component to the output terminal Tout. From this viewpoint, it is possible to accurately detect the amplitude of the differential signal.

### Fourth Embodiment

Next, an amplitude detector 400 according to a fourth embodiment is described. Hereinafter, portions which are different from the second embodiment are mainly described.

In the second embodiment, the amplitude detector 200 has a differential configuration, and in the fourth embodiment, the amplitude detector 400 has a non-differential configuration.

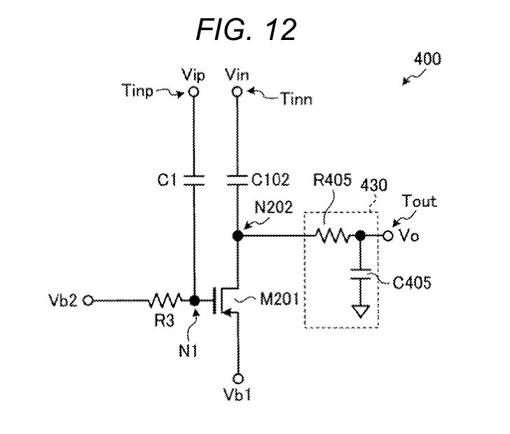

Specifically, as illustrated in FIG. 12, in the amplitude detector 400, one-sided configuration of the differential configuration illustrated in FIG. 6 is omitted, and the capacitive element (the third capacitive element) C3, the resistive element R101, the resistive element R102, the resistive element R4, and the amplitude detection transistor (the second amplitude detection transistor) M202 are not included. The amplitude detector 400 further includes a low-pass filter 430. FIG. 12 is a diagram illustrating a configuration of the amplitude detector 400.

The low-pass filter 430 is electrically connected between the node N202 and the output terminal Tout. The low-pass filter 430 includes a resistive element R405 and a capacitive element C405. The resistive element R405 is inserted into a line connecting the node N202 and the output terminal Tout. One end of the capacitive element C405 is connected to the ground potential, and the other end thereof is connected to the line connecting the node N202 and the output terminal Tout. Accordingly, the low-pass filter 430 is able to dampen a component having a frequency greater than or equal to a cutoff frequency among signals supplied from the node N202, and is able to transfer the signal to the output terminal Tout. When a resistance value of the resistive element R405 and a capacitance value of the capacitive element C405 are set such that the cutoff frequency is less than the fundamental frequency ωc, the low-pass filter 430 is able to eliminate the primary component and the secondary component among the signals supplied from the node N202, and is able to transfer the DC component to the output terminal Tout.

Furthermore, the fourth embodiment is identical to the second embodiment in that the amplitude detection transistor M201 receives the RF signal (the first signal) Vip on the P side by the gate, and receives the RF signal (the second signal) Vin on the N side by the drain.

Thus, in the amplitude detector 400 according to the fourth embodiment, the amplitude detection transistor M201 is able to detect the amplitude of the RF signals Vip and Vin while eliminating the influence of the in-phase component, and is able to supply the detection result in which the influence of the in-phase component is eliminated to the output terminal Tout. Accordingly, the output terminal Tout is able to output the amplitude signal Vo in which the influence of the in-phase component is eliminated in accordance with the amplitude detected by the amplitude detection transistor M201. That is, according to the fourth embodiment, it is possible to suppress the influence of the in-phase component, and it is possible to accurately detect the amplitude of the differential signal.

In addition, in the amplitude detector 400 according to the fourth embodiment, the low-pass filter 430 is able to eliminate the primary component and the secondary component among the signals supplied from the node N202, and is able to transfer the DC component to the output terminal Tout. From this viewpoint, it is possible to accurately detect the amplitude of the differential signal.

Application Example of Amplitude Detector

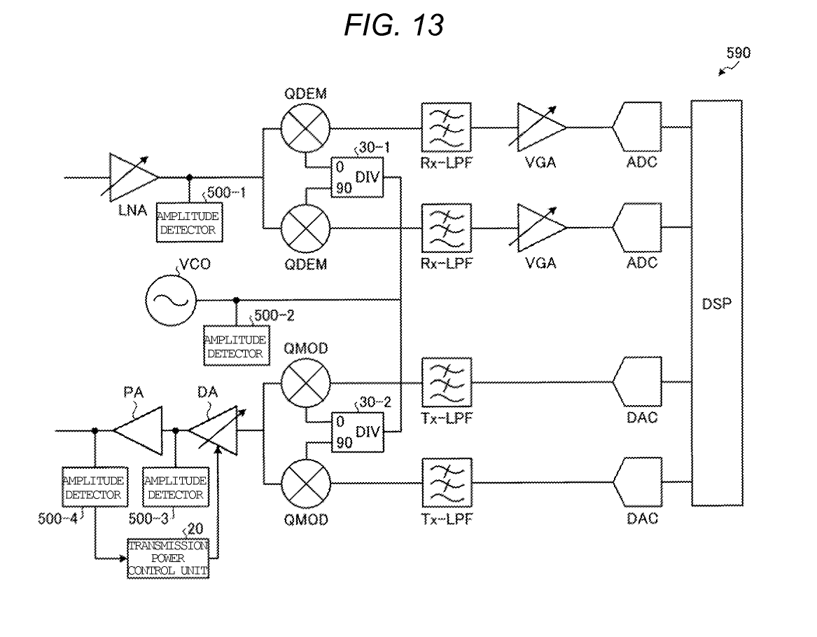

Next, a communication instrument 590 to which the amplitude detectors according to the first embodiment to the fourth embodiment are applied is described with reference to FIG. 13. FIG. 13 is a diagram illustrating a configuration of the communication instrument 590.

As illustrated in FIG. 13, the communication instrument 590 includes a low noise amplifier LNA, a quadrature demodulator QDEM, a low-pass filter for reception Rx-LPF, a variable amplifier VGA, an A/D converter ADC, a digital signal processing unit DSP, a D/A converter DAC, a low-pass filter for transmission Tx-LPF, a quadrature modulator QMOD, a driver amplifier DA, a power amplifier PA, a transmission power control unit 20, a voltage control oscillator VCO, synthesizer units 30-1 and 30-2, and a plurality of amplitude detectors 500-1 to 500-4.

The amplitude detector 500-1 may be used for correcting signal quality. For example, the amplitude detector 500-1 detects the amplitude of the differential signal output from the low noise amplifier LNA, and feeds back an amplitude signal in accordance with the detected amplitude to the digital signal processing unit DSP. According to this, the digital signal processing unit DSP controls a gain of the low noise amplifier LNA such that the received amplitude signal is in a target range. The target range is a range corresponding to a range determined by a communication standard with respect to the amplitude of the differential signal. The low noise amplifier LNA changes a gain according to control by the digital signal processing unit DSP, amplifies the differential signal by the changed gain, and supplies the differential signal to the quadrature demodulator QDEM. Accordingly, it is possible to monitor a signal level, and it is possible to adjust the gain or the digital signal of the low noise amplifier LNA to be a desired signal level (a signal level at which the signal quality is suitable).

In addition, the amplitude detector 500-2 may be used for controlling the signal level. For example, the amplitude detector 500-2 monitors an output level of the voltage control oscillator VCO, and feeds back a result thereof to the digital signal processing unit DSP. According to this, the digital signal processing unit DSP performs Auto Level Control (ALC) which controls the voltage control oscillator VCO such that the output level of the voltage control oscillator VCO is a target level. Accordingly, it is possible to perform signal output at a stable level.

In addition, the amplitude detector 500-3 may be used for correcting carrier leak. The carrier leak indicates that a carrier signal created by the synthesizer units 30-1 and 30-2 leaks into an outer portion of an integrated circuit (LSI) of the communication instrument 590, and it is necessary that the carrier leak be suppressed to be less than or equal to a defined amount. Systematically, an element property used in a circuit is completely matched, the carrier leak does not occur. However, practically, the element used in the integrated circuit (LSI) of the communication instrument 590 is mismatched, and thus the carrier leak may be a problem. For example, in order to correct the carrier leak, a reference signal for an I channel and a Q channel is created by the digital signal processing unit DSP, the amplitude of the output signal of the driver amplifier DA in accordance with the reference signal is detected by the amplitude detector 500-3, and the signal is fed back to the digital signal processing unit DSP. According to this, the digital signal processing unit DSP is able to perform carrier leak correction by adjusting the digital signal or an analog signal for each channel.

In addition, the amplitude detector 500-3 may be used for correcting an IQ mismatch. As one of important performance indexes of the transmitter 590 is modulation accuracy (EVM). In order to attain excellent EVM, it is necessary that an amplitude error and a phase error between the I channel and the Q channel be suppressed to be extremely small. For example, in order to correct the amplitude error and the phase error between the I channel and the Q channel, the reference signal for correcting the amplitude error and the phase error is created by the digital signal processing unit DSP, and the amplitude of the output signal of the driver amplifier DA in accordance with the reference signal is detected by the amplitude detector 500-3, and the signal is fed back to the digital signal processing unit DSP. According to this, the digital signal processing unit DSP is able to correct the amplitude error and the phase error by adjusting the digital signal.

In addition, the amplitude detector 500-4 may be used for controlling transmission power. For example, the amplitude detector 500-4 detects the amplitude of the differential signal output from the power amplifier PA, and supplies the amplitude signal in accordance with the detected amplitude to the transmission power control unit 20. The transmission power control unit 20 controls the gain of the driver amplifier DA such that the received amplitude signal is in the target range. The target range is a range corresponding to the range determined by the communication standard with respect to the amplitude of the differential signal. The driver amplifier DA changes the gain according to the control by the transmission power control unit 20, amplifies the differential signal by the changed gain, and supplies the differential signal to the power amplifier PA. Accordingly, the output signal (output power) of the power amplifier PA is monitored, and the gain of the driver amplifier DA is able to be controlled such that the gain is a desired output level.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An amplitude detector comprising:
a first amplitude detection transistor configured to receive a first signal by a gate, and a second signal forming a differential pair with the first signal by a drain and detect an amplitude of the differential pair; and
an output terminal configured to output an amplitude signal in accordance with amplitude detected by the first amplitude detection transistor.

2. The detector according to claim 1, further comprising:
a first input terminal to which the first signal is input;
a second input terminal to which the second signal is input;
a first capacitive element having one end connected to the first input terminal; and
a second capacitive element having one end connected to the second input terminal,
wherein the gate of the first amplitude detection transistor is connected to the other end of the first capacitive element, and the drain of the first amplitude detection transistor is connected to the other end of the second capacitive element.

3. The detector according to claim 1, further comprising:
a second amplitude detection transistor configured to receive the second signal by a gate, and the first signal by a drain, and detect an amplitude of the differential pair,
wherein the amplitude signal output through the output terminal is derived from the amplitude detected by the first amplitude detection transistor and amplitude detected by the second amplitude detection transistor.

4. The detector according to claim 3, further comprising:
a first input terminal to which the first signal is input;
a second input terminal to which the second signal is input;
a first capacitive element having one end connected to the first input terminal;
a second capacitive element having one end connected to the second input terminal;
a third capacitive element having one end connected to the second input terminal; and
a fourth capacitive element having one end connected to the first input terminal,
wherein the gate of the first amplitude detection transistor is connected to the other end of the first capacitive element, and the drain of the first amplitude detection transistor is connected to the other end of the second capacitive element, and
wherein the gate of the second amplitude detection transistor is connected to the other end of the third capacitive element, and the drain of the second amplitude detection transistor is connected to the other end of the fourth capacitive element.

5. The detector according to claim 4, further comprising:
a first resistive element that is connected between the first amplitude detection transistor and the output terminal; and
a second resistive element that is connected between the second amplitude detection transistor and the output terminal.

6. An amplitude detector comprising:
a differential pair of transistors having a common node connected to a first bias voltage, first and second inputs and first and second outputs;
first and second input resistors one end of each input resistor connected to a second bias voltage, the other end of the first input resistor connected to the first input, and the other end of the second input resistor connected to the second input;
first and second load resistors each of the load resistors having one end connected to a detector output node, the other end of the first load resistor connected to the first output, and the other end of the second load resistor connected to the second output;
first and second input capacitors; and
first and second load capacitors,
wherein one end of the first input capacitor and one end of the second load capacitor are connected to a positive voltage input,
wherein one end of the second input capacitor and one end of the first load capacitor are connected to a negative voltage input, and
wherein the other end of the first input capacitor is connected to the first input, the other end of the second input capacitor is connected to the second input, the other end of the first load capacitor is connected to the first output, and the other end of the second load capacitor is connected to the second output.

7. The amplitude detector according to claim 6, wherein the differential pair is a PMOS differential pair.

8. The amplitude detector according to claim 6, wherein the differential pair is a NMOS differential pair.

9. The amplitude detector according to claim 8, wherein the first bias voltage is a first reference potential.

10. The amplitude detector according to claim 6, further comprising a bias voltage generator that provides the second bias voltage.

11. The amplitude detector according to claim 10, wherein the bias generator includes:
a current source connected between a second bias voltage node and a first reference potential; and
a diode-connected transistor connected between the second bias voltage node and first bias voltage, the bias generator providing the second bias voltage at the second bias voltage node.

12. The amplitude detector according to claim 11,
wherein the differential pair is a PMOS differential pair; and
wherein the diode-connected transistor is a PMOS transistor having a source connected to the first bias voltage and a gate and drain connected to the second bias voltage.

13. The amplitude detector according to claim 11,
wherein the differential pair is a NMOS differential pair; and
wherein the diode-connected transistor is a NMOS transistor having a source connected to the first bias voltage and a gate and drain connected to the second bias voltage.

14. The amplitude detector according to claim 11, further comprising a first bias voltage source connected between a first bias voltage node and the first reference potential, the first voltage source providing the first bias voltage at the first bias voltage node.

15. The amplitude detector according to claim 6, further comprising a low-pass filter connected to the detector output node to provide a filtered detector output.

16. The amplitude detector according to claim 15, wherein the low-pass filter includes:
a resistor connected between the amplitude detector output and the filtered detector output; and
a capacitor connected between the filtered detector output and ground.
